(19) United States
(12) Patent Application Publication
(10) Pub. No.: US 2021/0217941 A1
(43) Pub. Date: Jul. 15, 2021

(54) Printed Circuit Board and Method of Manufacturing a Printed Circuit Board with at Least One Optoelectronic Component Integrated into the Printed Circuit Board

(71) Applicant: OSRAM OLED GmbH, Regensburg (DE)

(72) Inventor: Daniel Richter, Bad Abbach (DE)

(21) Appl. No.: 17/270,732

(22) PCT Filed: Aug. 13, 2019
(86) PCT No.: PCT/EP2019/071714

§ 371 Date: Feb. 23, 2021

(30) Foreign Application Priority Data
Aug. 23, 2018 (DE) 10 2018 120 637.2

(51) Int. Cl. H01L 33/62; H01L 33/54; H01L 25/075; H01L 23/00

(52) U.S. Cl. CPC H01L 33/62; H01L 33/54; H01L 25/0753; H01L 24/20; H01L 2924/12041; H01L 2933/005; H01L 2933/0066; H01L 2224/211; H01L 2224/2105; H01L 24/19

(57) ABSTRACT

In an embodiment a method for manufacturing a printed circuit board with at least one optoelectronic component integrated into the printed circuit board includes arranging the at least one optoelectronic component on a first metal layer, pressing a first electrically insulating layer onto the at least one optoelectronic component and creating at least one recess in the first metal layer and/or the first electrically insulating layer thereby at least partially exposing the at least one optoelectronic component, wherein the first electrically insulating layer comprises a fiber reinforced plastic or a glass fiber fabric.

This patent application is a national phase filing under section 371 of PCT/EP2019/071714, filed Aug. 13, 2019, which claims the priority of German patent application 10 2018 120 637.2, filed Aug. 23, 2018, each of which is incorporated herein by reference in its entirety.

### TECHNICAL FIELD

The present invention concerns a printed circuit board and a method of manufacturing a printed circuit board with at least one optoelectronic component integrated into the printed circuit board.

### BACKGROUND

Displays can comprise arrays of optoelectronic components such as LEDs. Usually, the optoelectronic components are arranged on substrates, such as printed circuit boards. The substrates contain metallization layers to couple the optoelectronic components with each other and to be able to drive them electrically.

### SUMMARY OF THE INVENTION

Embodiments provide a method by which a device with at least one optoelectronic component can be created in a cost-effective manner. Further embodiments provide a device.

A method of manufacturing a printed circuit board (PCB) having at least one optoelectronic component integrated in the printed circuit board comprises arranging at least one optoelectronic component on a first metal layer. A first electrically insulating layer is then pressed onto the at least one optoelectronic component. Furthermore, at least one recess is created in the first metal layer and/or the first electrically insulating layer. The at least one optoelectronic component is at least partially exposed through the at least one recess.

The printed circuit board manufactured by the method described in the present application comprises the first electrically insulating layer, the at least one optoelectronic component and the first metal layer which can in particular be structured. In addition, the printed circuit board may include further components.

The at least one optoelectronic component can emit light in the visible range, ultraviolet (UV) light and/or infrared (IR) light.

Furthermore, the at least one optoelectronic component can be an optoelectronic semiconductor component, in particular a semiconductor chip. For example, the at least one optoelectronic component can be a light emitting diode (LED), an organic light emitting diode (OLED), a light emitting transistor or an organic light emitting transistor. The at least one optoelectronic component can also be part of an integrated circuit.

In addition to the at least one optoelectronic component, further semiconductor components and/or other components can be integrated into the circuit board.

The first metal layer can be a metal foil, which is usually used in the production of printed circuit boards. For example, the first metal layer can consist of copper or any other suitable metal or of any suitable metal alloy. The first metal layer may be unstructured during the arrangement of the at least one optoelectronic component on the first metal layer.

The at least one optoelectronic component can be fixed to the first metal layer with the help of an electrically non-conductive adhesive.

The first electrically insulating layer can be a polymer, a fiber-reinforced plastic, a laminate, a glass fiber fabric or any other suitable material that is commonly used in the manufacturing of printed circuit boards.

While pressing the first electrically insulating layer onto the at least one optoelectronic component, a suitable pressure can be applied. In addition, the electrically insulating layer may be heated during the pressing of the first electrically insulating layer onto the at least one optoelectronic component. By pressing the electrically insulating layer onto the at least one optoelectronic component, the at least one optoelectronic component is integrated into the electrically insulating layer, i.e. directly after the pressing process, a main surface and one or more side surfaces, in particular all side surfaces of the at least one optoelectronic component can be covered by the material of the first electrically insulating layer.

The at least one recess can be created in the first metal layer and/or the first electrically insulating layer using a suitable method. For example, the at least one recess can be created by a laser beam with which material of the first metal layer and/or the first electrically insulating layer is removed in order to at least partially expose the at least one optoelectronic component. Alternatively, it is also conceivable to use another suitable method for producing the at least one recess, for example an etching process.

Furthermore, the method used to create the at least one recess can also be used to create one or more through holes in the first electrically insulating layer. The through hole(s) is (are) located laterally next to the at least one optoelectronic component and extend from the top to the bottom of the electrically insulating layer.

With the method described herein, the printed circuit board with the at least one optoelectronic component integrated into it can be manufactured in a cost-effective manner. It is not necessary to first manufacture the printed circuit board and then mount the at least one optoelectronic component on the printed circuit board. Instead, the assembly of the at least one optoelectronic component is integrated into the circuit board manufacturing process. Reshaping, contacting and exposing of the at least one optoelectronic component can be done by standard process steps which are used to produce a printed circuit board anyway. Complex steps, such as the creation of bonding wires, the encapsulation of semiconductor chips, the black or white edging of semiconductor chips, and the mounting and contacting of semiconductor chips on the circuit board can be eliminated. Furthermore, the infrastructure that a printed circuit board offers can be used. For example, several optoelectronic components can be electrically coupled together using the metallization layers of the printed circuit board. A CoB (chip on board) module can be manufactured in a very cost-effective process flow.

Printed circuit boards produced with the method described herein can be used in many LED applications, for example in LED displays. Furthermore, the printed circuit boards can be used in lighting devices, e.g. in atmosphere lighting, in particular for vehicles, or in flash lights. Applications in backlightings are also conceivable, e.g. for backlighting of screens or switches. The use in more complex modules is also conceivable, e.g. in pixelated light sources or in tiles of video walls.

By creating the at least one recess, a surface of the at least one optoelectronic component, through which the light generated by the at least one optoelectronic component at least partially emerges, can be partially or completely exposed.

It can be intended that together with the first electrically insulating layer a second metal layer is pressed onto the at least one optoelectronic component. After the second metal layer has been arranged, the first electrically insulating layer and the at least one optoelectronic component integrated into the first electrically insulating layer are arranged between the first metal layer and the second metal layer.

The second metal layer can be a metal foil, which is usually used in the manufacturing of printed circuit boards. For example, the second metal layer can consist of copper or any other suitable metal or of a suitable metal alloy. The second metal layer may be unstructured when arranged on the at least one optoelectronic component. The second metal layer can be structured in a later process step. Furthermore, the at least one recess can extend through the second metal layer. In this case, the second metal layer is removed at the corresponding position(s) to create the at least one recess.

According to an embodiment, the at least one optoelectronic component comprises a first main surface and a second main surface opposite to the first main surface. The two main surfaces are connected by side surfaces. The at least one optoelectronic component is arranged with its first main surface on the first metal layer. Light generated by the at least one optoelectronic component is emitted through the second main surface and in particular through the side surfaces as well.

The at least one optoelectronic component can be a semiconductor chip of the so-called flip-chip type, which has all its electrical contact elements on the first main surface, which after assembly is directed towards the first metal layer. Furthermore, the at least one optoelectronic component can be a sapphire chip of the flip-chip type. A sapphire flip-chip comprises one or more layers of semiconductor material in which light is generated. Above the semiconductor layers is a layer of aluminum oxide, Al₂O₃, through which the light is emitted.

By creating the at least one recess, the second main surface of the at least one optoelectronic component, through which at least part of the light generated by the at least one optoelectronic component is emitted, can be partially or completely exposed. Furthermore, material of the first electrically insulating layer, which is located laterally of the second main surface, can be removed. In other words, the at least one recess can protrude above the second main surface. Consequently, in this case the base area of the at least one recess is larger than the second main surface of the at least one optoelectronic component. This allows an unhindered emission of the emitted light and prevents shadowing effects.

According to an embodiment, the first electrically insulating layer contains light absorbing or black material. For example, the first electrically insulating layer may contain soot particles or other black particles as light absorbing material. This allows a good black impression of the PCB to be achieved.

In this context, light-absorbing means that the light-absorbing material absorbs at least part of the light emitted by the at least one optoelectronic component or at least light in a certain wavelength range.

Alternatively to the aforementioned embodiment, the first electrically insulating layer can contain light reflecting material. For example, the first electrically insulating layer can contain titanium dioxide, TiO₂, or particles of titanium dioxide as light reflecting material. For volume emitters, where the light is emitted not only on a main surface but also on the side surfaces, e.g. sapphire chips, this embodiment can be advantageous to direct the light emitted on the side surfaces in the desired direction.

Reflective in this context means that the reflecting material is reflective at least for a part of the light emitted by the at least one optoelectronic component or at least for light in a certain wavelength range.

In order to create a high contrast, a further layer can be applied to the first electrically insulating layer with the light-reflecting material contained therein, wherein the further layer contains light-absorbing material, e.g. soot particles. The further layer can, for example, be laminated to the underlying layers by applying pressure and heat. In the following steps the further layer can be structured to create the at least one recess. The second metal layer can also be between the first electrically insulating layer and the further layer.

A first structured metallization layer can be deposited on the at least one optoelectronic component, the first metal layer and/or the first electrically insulating layer. The first structured metallization layer can in particular be configured for rewiring the electrical contact elements of the at least one optoelectronic component. Furthermore, several optoelectronic components can be coupled together by the first structured metallization layer.

The first structured metallization layer can be produced by electroplating. The first structured metallization layer can be produced at least partially on the first metal layer and/or the second metal layer. The first metal layer and/or the second metal layer can thereby be structured. Furthermore, the first structured metallization layer can extend through through holes in the first electrically insulating layer to create vias (vertical interconnect access), through which in particular the first metal layer and the second metal layer are electrically coupled.

A second electrically insulating layer can be arranged or laminated onto the first structured metallization layer. Furthermore, a second structured metallization layer can be arranged on the second electrically insulating layer. Through holes in the second electrically insulating layer can electrically connect the first structured metallization layer with the second structured metallization layer. Further layers can be produced in the same way, each containing an electrically insulating layer, a structured metallization layer and vias through the electrically insulating layer. Any number of such layers can be combined. The layers described above may be necessary to create a sufficiently high component and to meet requirements for component height and/or to realize a desired rewiring of the electrical contact elements of the at least one optoelectronic component. Furthermore, a so-called fan-out area can be created, which makes it possible to place the external contact elements of the printed circuit board outside the outline of the at least one optoelectronic component, for example to increase the contact distances or to create a desired pattern of the external contact elements.

A printed circuit board comprises a first electrically insulating layer, at least one optoelectronic component integrated into the first electrically insulating layer, a first structured metallization layer extending over the first electrically insulating layer and the at least one optoelectronic component, and at least one recess in the first electrically insulating layer by which the at least one optoelectronic component is at least partially exposed.

The printed circuit board can comprise the embodiments described above in connection with the method for manufacturing the printed circuit board.

The at least one recess can at least partially expose a surface of the at least one optoelectronic component through which at least a portion of the light generated by the at least one optoelectronic component emerges.

Furthermore, the at least one recess can be larger than the surface of the at least one optoelectronic component through which the light generated by the at least one optoelectronic component emerges.

The first electrically insulating layer can comprise light absorbing material.

Alternatively, the first electrically insulating layer can comprise light-reflecting material. In addition, a further layer containing light-absorbing material can be arranged on the first electrically insulating layer.

A second electrically insulating layer can be arranged on the first structured metallization layer and a second structured metallization layer can be arranged on the second electrically insulating layer. Through holes in the second electrically insulating layer can electrically couple the first structured metallization layer with the second structured metallization layer.

A display, i.e. a visual indicator, can comprise one or more of the circuit boards described above. In addition, a printed circuit board contained in the display can be manufactured using the method described above.

A circuit board integrated into the display can comprise a pixel matrix. Each of the pixels can have three subpixels with a respective optoelectronic component, wherein the subpixels emit light of the colors red, green and blue.

### BRIEF DESCRIPTION OF THE DRAWINGS

In the following, embodiments of the invention are explained in detail with reference to the attached drawings.

FIG. 1A to 1E show illustrations of an embodiment of a method of manufacturing a printed circuit board with several LED semiconductor chips integrated into the printed circuit board;

FIG. 2A to 2D show illustrations of an embodiment of a method of manufacturing a printed circuit board with several LED semiconductor chips integrated into the printed circuit board and a first electrically insulating layer with light absorbing material;

FIG. 3A to 3D show illustrations of an embodiment of a method of manufacturing a printed circuit board with several LED semiconductor chips integrated into the printed circuit board and a first electrically insulating layer with light-reflecting material as well as a further layer with light-absorbing material arranged on the first electrically insulating layer;

FIGS. 4A to 4E show illustrations of an embodiment of a method of manufacturing a printed circuit board with several LED semiconductor chips integrated into the printed circuit board and an additional rewiring layer; and

FIGS. 5A and 5B show illustrations of an embodiment of a circuit board with a pixel matrix.

In the following detailed description, reference is made to the attached drawings, which form part of this description and in which, for illustration purposes, specific examples of embodiments are shown in which the invention can be exercised. Since components of embodiments can be positioned in a number of different orientations, the terminology of directions is for illustration purposes only and is in no way restrictive. It is understood that other embodiments can be used and structural or logical changes can be made without deviating from the scope of protection. It is understood that the features of the different embodiments described herein may be combined with each other, unless specifically stated otherwise. The following detailed description should therefore not be understood in a restrictive way. In the figures, identical or similar elements are marked with identical reference signs, where appropriate.

### DETAILED DESCRIPTION OF ILLUSTRATIVE EMBODIMENTS

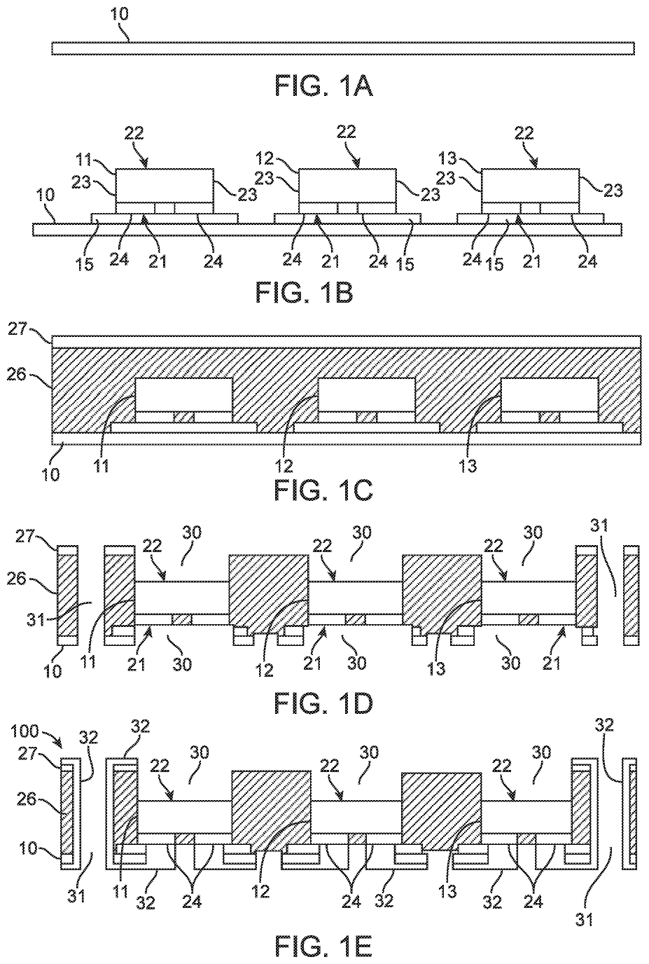

FIGS. 1A to 1E schematically show an embodiment of a method of manufacturing a printed circuit board with at least one optoelectronic component integrated into the printed circuit board. FIG. 1E schematically shows an embodiment of a printed circuit board manufactured by the method.

In FIG. 1A, a first metal layer is provided in form of a copper foil 10.

FIG. 1B shows that several optoelectronic components are placed on copper foil 10. In the present embodiment, three LED semiconductor chips 11, 12 and 13 are fixed on copper foil 10 using an electrically non-conductive adhesive 15.

Each of the LED semiconductor chips 11, 12 and 13 has a first main surface 21, a second main surface 22 opposite to the first main surface 21, and four side surfaces 23 connecting the first and second main surfaces 21, 22. The LED semiconductor chips 11, 12 and 13 are flip-chip semiconductor chips whose electrical contact elements 24 are arranged exclusively on the first main surface 21. After mounting, the first main surface 21 faces the copper foil 10. The electrically non-conductive adhesive 15 is arranged between the electrical contact elements 24 of the LED semiconductor chips 11, 12 and 13 and the copper foil 10.

In the present embodiment, the LED semiconductor chip 11 is configured to emit green light. The LED semiconductor chips 12 and 13 are configured to emit red and blue light, respectively. The LED semiconductor chips 11, 12 and 13 can be surface emitters, which emit light only on the second main surface 22, but can also be volume emitters, which emit light on the second main surface 22 and additionally on the side surfaces 23. In the present embodiment, the LED semiconductor chips 11, 12 and 13 are sapphire flip chips.

LED semiconductor chips 11, 12 and 13 are bonded with a first electrically insulating layer 26, which is made of a suitable polymer, and a second metal layer in the form of a copper foil 27, as shown in FIG. 1C. The first electrically insulating layer 26 and the copper foil 27 arranged thereon are pressed onto the LED semiconductor chips 11, 12 and 13 by applying pressure and heat. After this step, the second main surfaces 22 and the side surfaces 23 of the LED semiconductor chips 11, 12, and 13 are covered by the first electrically insulating layer 26.

In FIG. 1D, several recesses 30 are created with a laser in the copper foils 10 and 27 and the first electrically insulating layer 26. This exposes the first and second main surfaces 21 and 22 of the LED semiconductor chips 11, 12 and 13. Furthermore, the copper foil 27 is removed in the area between the LED semiconductor chips 11, 12 and 13. In the present embodiment, the first electrically insulating layer 26 laterally from the LED semiconductor chips 11, 12 and 13 is not removed.

Furthermore, the laser is used to create through holes 31 laterally adjacent to the LED semiconductor chips 11, 12 and 13, which extend completely through the copper foil 10, the first electrically insulating layer 26 and the copper foil 27.

Finally, as FIG. 1E shows, a first structured metallization layer 32 is deposited on the electrical contact elements 24 of the LED semiconductor chips 11, 12 and 13, the copper foils 10 and 27, and in the through-holes 31. The first structured metallization layer 32 is produced by electroplating and can consist of one or more metal layers, in particular copper layers. Vias are created by depositing metal in the through holes 31.

FIG. 1E shows a cross section of the printed circuit board 100 manufactured with the aforementioned method. The second main surfaces 22 of the LED semiconductor chips 11, 12, and 13 are exposed, such that an Emission of the generated light against air is achieved.

Through the first structured metallization layer 32, external contact elements can be formed on the bottom and top side of the circuit board 100, through which the LED semiconductor chips 11, 12 and 13 can be electrically controlled from outside.

The manufacturing process makes it possible to manufacture a large-area printed circuit board 100 or several printed circuit boards 100 simultaneously. If necessary, the PCBs 100 can be separated after production, for example by sawing.

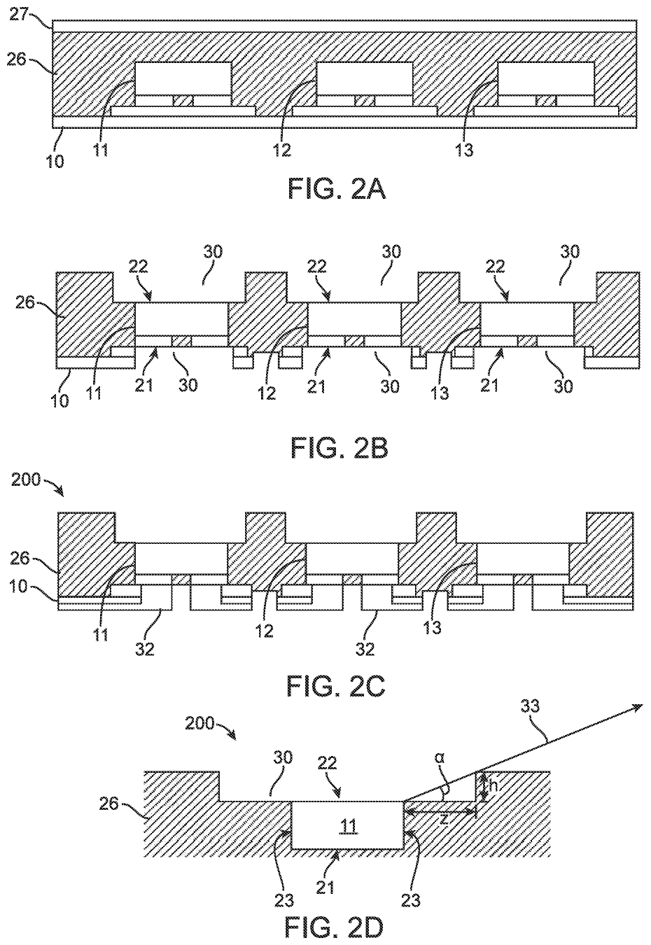

FIGS. 2A to 2D schematically show another embodiment of a method of manufacturing a printed circuit board. FIG. 2C shows a cross-section of the PCB 200 manufactured by this method.

The method shown in FIGS. 2A to 2D is a further development of the method shown in FIGS. 1A to 1E and therefore partially similar to the method shown in FIGS. 1A to 1E.

FIG. 2A shows LED semiconductor chips 11, 12 and 13 pressed with the first electrically insulating layer 26 and copper foil 27. Unlike FIG. 1C, the first electrically insulating layer 26 in FIG. 2A contains black or light-absorbing material or a filler. This material can consist of soot particles, for example.

FIG. 2B shows that several recesses 30 are created with a laser in the copper foil 10 and the first electrically insulating layer 26. The copper foil 27 is removed. As in FIG. 1D, the first and second main surfaces 21 and 22 of the LED semiconductor chips 11, 12 and 13 are exposed. In addition, the material of the first electrically insulating layer 26 is removed not only directly above the LED semiconductor chips 11, 12 and 13, but also laterally next to the LED semiconductor chips 11, 12 and 13 to avoid shadowing effects. Consequently, the base surfaces of the recesses 30 above the LED semiconductor chips 11, 12, and 13 are larger than the second main surfaces 22 of the LED semiconductor chips 11, 12, and 13.

In FIG. 2C, the first structured metallization layer 32 is deposited in the same way as in the embodiment in FIG. 1A to 1E.

FIG. 2D shows an enlarged section of the finished circuit board 200, which is intended to illustrate a dimension to determine the dimensions of the recesses 30 above the LED semiconductor chips 11, 12 and 13. In FIG. 2D, the height of the recess 30 is denoted by h and the width of the area laterally adjacent to the side face 23 of the LED semiconductor chip 11, where the material of the first electrically insulating layer 26 was removed to form the recess 30, is denoted by z. Furthermore, FIG. 2D shows a light beam 33, which indicates the propagation of light emitted at the outermost edge of the second main surface 22 of the LED semiconductor chip 11 and which is emitted into the environment just above the upper edge of the recess 30.

The light beam 33 forms an angle α with the second main surface 22 of the LED semiconductor chip 11 and the base surface of the recess 30. The following relationship also applies:

$$tan α = \frac{h}{z} \qquad ( 1 )$$

If a critical value for the angle α is given, equation (1) can be used to determine values for the height h and width z. If the height h is also given, the width z can be determined directly.

For example, a viewing angle of 150° is usually required for video wall applications. Accordingly, the critical value for the angle α is 15°. With this value and equation (1) values for the height h and width z can be determined.

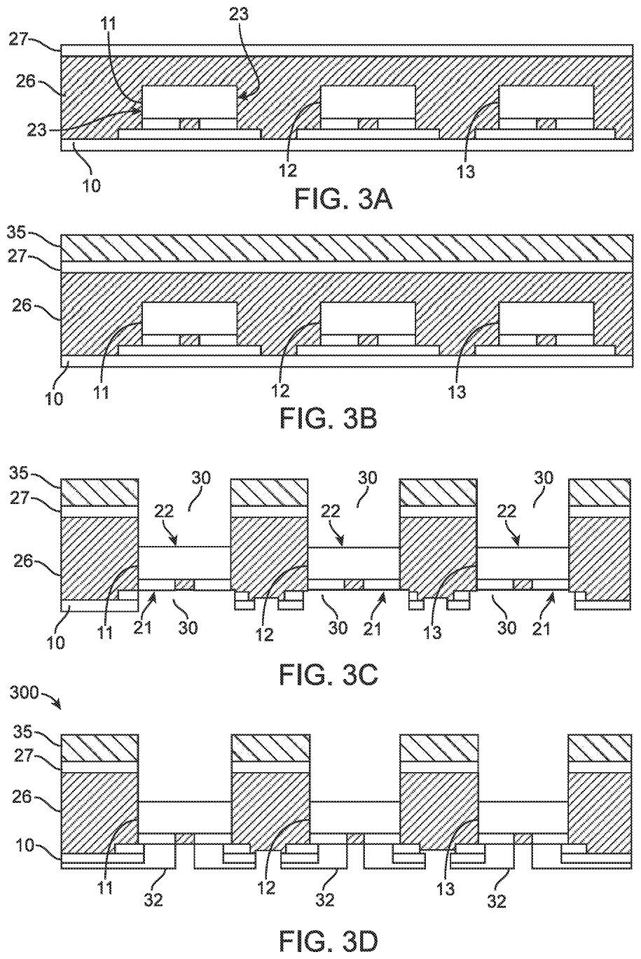

FIG. 3A to 3D schematically show another embodiment of a method of manufacturing a printed circuit board. FIG. 3D shows a cross-section of the PCB 300 manufactured by this method.

The method shown in FIGS. 3A to 3D is a further development of the method shown in FIGS. 1A to 1E. In the following, only the differences to the method shown in FIGS. 1A to 1E are described.

FIG. 3A shows the LED semiconductor chips 11, 12 and 13 pressed together with the first electrically insulating layer 26 and the copper foil 27. Unlike FIG. 1C, the first electrically insulating layer 26 in FIG. 2A contains white or light reflective material or a filler. This material can consist of titanium dioxide, for example, and serves to reflect the light that actually leaves the side surfaces 23 of the LED semiconductor chips 11, 12 and 13.

As shown in FIG. 3B, in order to achieve a high contrast, a further layer 35 is laminated onto copper foil 27, which contains black or light-absorbing material, e.g. soot particles.

In the laser processing shown in FIG. 3C, the further layer 35 is also structured to create the recesses 30 above the LED semiconductor chips 11, 12 and 13.

In FIG. 3D, the first metallization layer 32 is deposited and structured as described above.

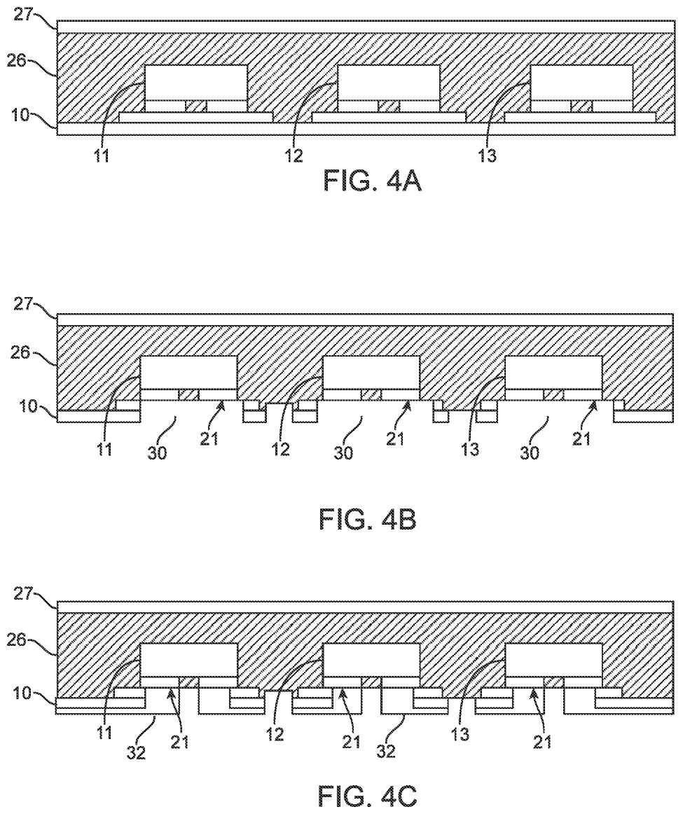

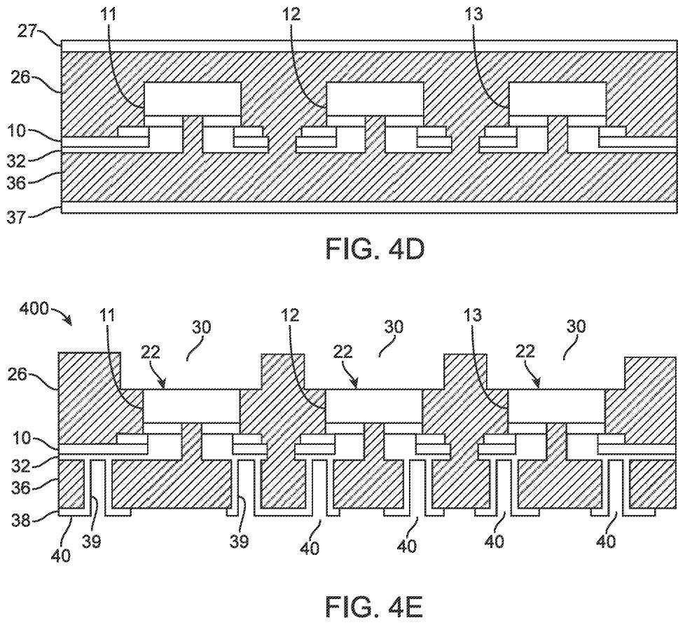

FIGS. 4A to 4E schematically show another embodiment of a method of manufacturing a printed circuit board, which is a further development of the method shown in FIGS. 2A to 2D. FIG. 4E shows a cross-section of the PCB 400 manufactured by the method.

FIG. 4A shows the LED semiconductor chips 11, 12 and 13 pressed together with the first electrically insulating layer 26 and the copper foil 27, wherein the first electrically insulating layer 26 contains black or light-absorbing material or a filler, e.g. soot particles.

In FIG. 4B, recesses 30 are created using a laser beam to expose the first main surfaces 21 of the LED semiconductor chips 11, 12 and 13.

In FIG. 4C, the first metallization layer 32 is electroplated and structured on the first main surfaces 21 of the LED semiconductor chips 11, 12 and 13 and the copper foil 10.

In FIG. 4D, a second electrically insulating layer 36 and further copper foil 37 are laminated to the first metallization layer 32. Like the first electrically insulating layer 26, the second electrically insulating layer 36 can contain black or light absorbing material or a filler.

FIG. 4E shows that a laser beam is used to create recesses 30 in the first electrically insulating layer 26 as well as through holes in the second electrically insulating layer 36. Furthermore, a second metallization layer 38, for example of copper, is arranged on the second electrically insulating layer 36 and structured. The second metallization layer 38 extends into the through-holes in the second electrically insulating layer 36, creating vias 39 which electrically couple the first and second structured metallization layers 32 and 38.

By means of the second electrically insulating layer 36, the second structured metallization layer 38 and optionally other such layers, a fan-out area can be created, which makes it possible to arrange external contact elements 40 of the circuit board 400 outside the outlines of the LED semiconductor chips 11, 12 and 13. The distances between adjacent external contact elements 40 can be at least 250 μm to be suitable for standard soldering processes.

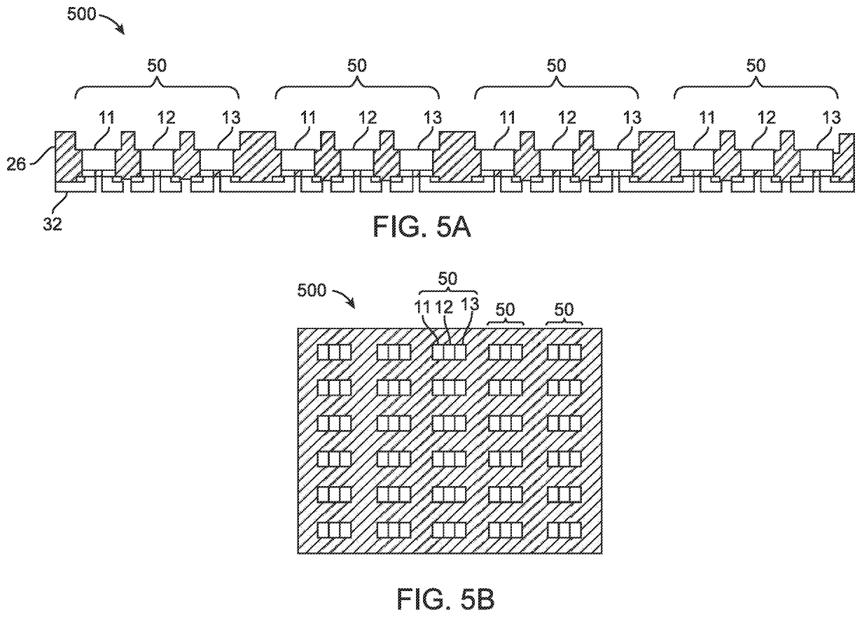

FIGS. 5A and 5B show a PCB 500 in cross section and in a top view, respectively. The printed circuit board 500 can be used in a display.

The PCB 500 comprises a pixel matrix with a plurality of pixels 50. Each of the pixels comprises three sub-pixels, wherein each of the subpixels is formed by LED semiconductor chips 11, 12 and 13, which emit light in the colors red, green and blue.

Printed Circuit Board 500 can be manufactured using the method shown in FIG. 2A to 2D.

Although the invention has been illustrated and described in detail by means of the preferred embodiment examples, the present invention is not restricted by the disclosed examples and other variations may be derived by the skilled person without exceeding the scope of protection of the invention.

1-18. (canceled)

19. A method for manufacturing a printed circuit board with at least one optoelectronic component integrated into the printed circuit board, the method comprising:
arranging the at least one optoelectronic component on a first metal layer;
pressing a first electrically insulating layer onto the at least one optoelectronic component; and
creating at least one recess in the first metal layer and/or the first electrically insulating layer thereby at least partially exposing the at least one optoelectronic component,
wherein the first electrically insulating layer comprises a fiber reinforced plastic or a glass fiber fabric.

20. The method according to claim 19, wherein creating the at least one recess comprises at least partially exposing a surface of the at least one optoelectronic component so that light generated by the at least one optoelectronic component is emittable through the exposed surface.

21. The method according to claim 19, further comprising pressing a second metal layer onto the at least one optoelectronic component together with the first electrically insulating layer.

22. The method according to claim 19, wherein the at least one optoelectronic component comprises a first main surface and a second main surface opposite the first main surface, wherein the at least one optoelectronic component is arranged with its first main surface on the first metal layer, and wherein the second main surface is configured to emit light.

23. The method according to claim 22, wherein creating the at least one recess comprises at least partially exposing the second main surface of the at least one optoelectronic component, and removing material of the first electrically insulating layer located laterally of the second main surface.

24. The method according to claim 19, wherein the first electrically insulating layer comprises a light absorbing material.

25. The method according to claim 19, wherein the first electrically insulating layer comprises a light reflecting material.

26. The method according to claim 25, further comprising arranging a further layer comprising light-absorbing material on the first electrically insulating layer.

27. The method according to claim 19, further comprising arranging a first structured metallization layer on the at least one optoelectronic component, the first metal layer and/or the first electrically insulating layer.

28. The method according to claim 27, further comprising:
arranging a second electrically insulating layer on the first structured metallization layer; and
arranging a second structured metallization layer on the second electrically insulating layer,
wherein vias in the second electrically insulating layer electrically couple the first structured metallization layer with the second structured metallization layer.

29. A printed circuit board comprising:
a first electrically insulating layer;
at least one optoelectronic component integrated into the first electrically insulating layer;
a first structured metallization layer extending over the first electrically insulating layer and the at least one optoelectronic component; and
at least one recess in the first electrically insulating layer at least partially exposing the at least one optoelectronic component,
wherein the first electrically insulating layer comprises a fiber reinforced plastic or a glass fiber fabric.

30. The printed circuit board according to claim 29, wherein the at least one recess at least partially exposes a surface of the at least one optoelectronic component so that light generated by the at least one optoelectronic is emittable through the exposed surface.

31. The printed circuit board according to claim 30, wherein the at least one recess is larger than the surface of the at least one optoelectronic component.

32. The printed circuit board according to claim 29, wherein the first electrically insulating layer comprises a light absorbing material.

33. The printed circuit board according to claim 29, wherein the first electrically insulating layer comprises a light reflective material.

34. The printed circuit board according to claim 33, further comprising a further layer comprising light-absorbing material arranged on the first electrically insulating layer.

35. The printed circuit board according to claim 29, further comprising:
a second electrically insulating layer arranged on the first structured metallization layer; and
a second structured metallization layer arranged on the second electrically insulating layer,
wherein vias in the second electrically insulating layer electrically couple the first structured metallization layer with the second structured metallization layer.

36. A display comprising:
one or more printed circuit boards according to claim 29.
